(19) United States
(12) Patent Application Publication
(10) Pub. No.: US 2010/0143710 A1
(43) Pub. Date: Jun. 10, 2010

(54) HIGH RATE DEPOSITION OF THIN FILMS WITH IMPROVED BARRIER LAYER PROPERTIES

(75) Inventors: Eric R. Dickey, Portland, OR (US); William A. Barrow, Beaverton, OR (US)

Correspondence Address: STOEL RIVES LLP - PDX, 900 SW FIFTH AVENUE, SUITE 2600, PORTLAND, OR, 97204-1268, US

(73) Assignee: Lotus Applied Technology, LLC, Beaverton, OR (US)

(21) Appl. No.: 12/632,749

(22) Filed: Dec. 7, 2009

Related U.S. Application Data
(60) Provisional application No. 61/161,287, filed on Mar. 18, 2009.
(60) Provisional application No. 61/120,381, filed on Dec. 5, 2008.

(51) Int. Cl. B32B 5/00; C23C 16/40; C23C 16/513; B05D 1/00; B05D 3/04

(52) U.S. Cl. 428/336; 427/255.395; 427/576; 427/209; 427/535

(57) ABSTRACT

An atomic layer deposition (ALD) method is utilized to deposit a thin film barrier layer of a metal oxide, such as titanium dioxide, onto a substrate. Excellent barrier layer properties can be achieved when the titanium oxide barrier is deposited by ALD at temperatures below approximately 100° C. Barriers less than 100 angstroms thick and having a water vapor transmission rate of less than approximately 0.01 grams/m²/day are disclosed, as are methods of manufacturing such barriers.

### RELATED APPLICATIONS

This application claims the benefit under 35 U.S.C. §119(e) from U.S. Provisional Patent Application No. 61/120,381, filed Dec. 5, 2008, and 61/161,287, filed Mar. 18, 2009, both of which are incorporated herein by reference.

### TECHNICAL FIELD

The field of this disclosure relates to thin film deposition systems and methods for forming thin-film barrier layers on substrates.

### BACKGROUND

Gases, liquids, and other environmental factors may cause deterioration of various goods, such as food, medical devices, pharmaceutical products, and electrical devices. Thus, traditionally, barrier layers have been included on or within the packaging associated with the sensitive goods to prevent or limit the permeation of gases or liquids, such as oxygen and water, through the packaging during manufacturing, storage, or use of the goods.

For example, complex multilayer barrier layers including five or six pairs of alternating organic and inorganic layers have been used to prevent the permeation of oxygen and water through plastic substrates of organic light emitting diodes (OLEDs). However, such multilayer barriers result in an overall barrier thickness that is not ideal for thin film flexible packaging. Additionally, many known multilayer barriers have been found to simply have long lag times rather than actually reducing steady state permeability.

Atomic layer deposition (ALD) is a thin film deposition process briefly described in the background section of U.S. Patent Application Publication No. US 2007/0224348 A1 of Dickey et al., filed Mar. 26, 2007 as U.S. application Ser. No. 11/691,421 and entitled Atomic Layer Deposition System and Method for Coating Flexible Substrates, which is incorporated herein by reference. A conventional cross-flow ALD reactor consists of a vacuum chamber held at a specific temperature through which a steady stream of inert carrier gas flows. An ALD deposition cycle consists of injecting a series of different precursors into this gas flow with intermediate purging by the inert carrier gas. The purge times between precursor pulses are sufficient to remove essentially all of the preceding precursor from the volume of the reaction chamber before the start of the next precursor pulse. After purging a first precursor from the reaction chamber, just a monolayer of that precursor is left on all surfaces within the chamber. The subsequent precursor reacts with the monolayer of the previous precursor to form molecules of the compound being deposited. The total cycle time for conventional cross-flow ALD at temperatures above 100° C. is on the order of 10 seconds per cycle. At room temperature, the cycle time for conventional cross-flow ALD is on the order of 100 seconds, due to the increased purge times required.

ALD processes have been used to deposit single layer barriers of aluminum oxide (Al₂O₃) or hafnium oxide (HfO₂) on substrates to prevent the permeation of oxygen and water. However, single layer barriers of Al₂O₃ created by an ALD process using trimethylaluminum (TMA) and water as precursors have been shown to have a lower density and poor barrier properties when deposited at temperatures below 100° C. Historically, attempts to improve barrier properties have included increasing barrier layer thickness, increasing substrate temperature (e.g., to over 150° C.), or both.

The present inventors have recognized a need for improved systems and methods for forming barrier layers on substrates.

### SUMMARY

In accordance with an embodiment, an ALD process involving a first precursor including TiCl₄ and an oxygen-containing second precursor, such as water, is used to form a barrier layer of titanium dioxide (TiO₂) on a substrate to inhibit the permeation therethrough of gases or liquids, such as oxygen, water vapor and chemicals. Excellent barrier layer properties can be achieved when the TiO₂ barrier layer is deposited at substrate temperatures less than approximately 100° C., and preferably between approximately 5° C. and approximately 80° C. Various methods may be used to form the barrier of TiO₂ on the substrate, such as a pulse sequence (e.g., sequentially exposing the substrate to TiCl₄ and water) or a roll-to-roll process (e.g., when the substrate travels between precursor zones). Experimental results have shown that barrier layers having a thickness of less than approximately 100 angstroms (100 Å) produced by the ALD processes described herein exhibit water vapor transmission rates (WVTR) of less than approximately 0.01 grams per square meter per day (g/m²/day).

As one skilled in the art will appreciate in view of the teachings herein, certain embodiments may be capable of achieving certain advantages, including by way of example and not limitation one or more of the following: (1) providing a barrier of TiO₂ on a substrate to inhibit the permeation of gases or liquids there through; (2) forming a barrier having a WVTR of less than approximately 0.5 g/m²/day on a substrate at a temperature of less than approximately 100° C.; (3) forming a barrier having a WVTR of less than approximately 0.5 g/m²/day on a substrate using a roll-to-roll ALD process; (4) forming a barrier of TiO₂ on a substrate that is resistant to corrosive environments; (5) forming a barrier of TiO₂ on a substrate that resists permeation of water vapor in high temperature environments, high humidity environments, or both; (6) forming an elastic barrier of TiO₂ on a flexible substrate; (7) forming a barrier of TiO₂ on a substrate at a temperature that reduces stress between the barrier layer and the substrate caused by differences in coefficients of thermal expansion between the barrier and the substrate; (8) providing a system and method for forming a barrier on a substrate at a temperature that allows for a greater range of materials and components to be used; (9) providing a system and method for forming a barrier on a substrate at a temperature that reduces power consumption by eliminating or reducing the need for heaters; (10) providing a low cost system and method for forming a barrier of TiO₂ on a substrate; (11) forming a chemical barrier having a WVTR of less than approximately 0.5 g/m²/day on a substrate; (12) forming an anti-bacterial barrier having a WVTR of less than approximately 0.5 g/m²/day on a substrate; and (13) forming a self-cleaning barrier having a WVTR of less than approximately 0.5 g/m²/day on a substrate. These and other advantages of various embodiments will be apparent upon reading the following.

### BRIEF DESCRIPTION OF THE DRAWINGS

FIG. 1 is a cross-section of a barrier layer formed on a substrate, according to one embodiment.

FIG. 2 is a cross-section of a barrier layer formed on both sides a substrate, according to another embodiment.

FIG. 3 is a plot of the reflectance (at 400 nm) of low temperature TiO₂ barrier formed on a PET substrate versus thickness, according to one embodiment.

FIG. 4 is a plot of water vapor transmission rate versus substrate temperature for a TiO₂ barrier formed on a PET substrate, according to one embodiment.

FIG. 5 is a schematic cross-section view illustrating an example loop mode configuration of a flexible web coater system.

FIG. 6 is a schematic cross-section view of flexible web coater system configured for roll-to-roll deposition.

FIG. 7 is a plot of water vapor transmission rates for PET films coated on both sides with 60 Å and 90 Å TiO₂ films deposited with a conventional cross-flow ALD reactor.

FIG. 8 is a plot of water vapor transmission rates for PET films coated with various thicknesses of TiO₂ in a flexible web coater system operating in loop mode.

### DETAILED DESCRIPTION OF PREFERRED EMBODIMENTS

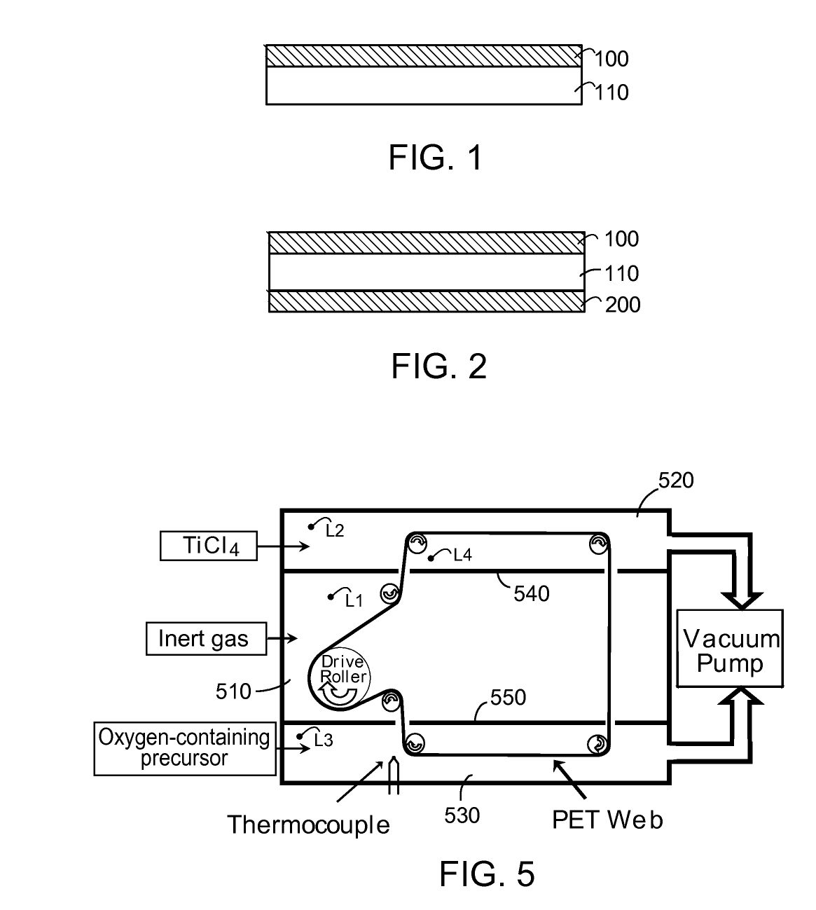

FIG. 1 is a cross-section view of a barrier layer or film 100 formed on a substrate 110, according to one embodiment. According to one embodiment, the barrier 100 comprises TiO₂ having a WVTR of less than approximately 0.01 g/m²/day. According to another embodiment, the barrier 100 comprises TiO₂ having a WVTR of less than approximately 0.0001 g/m²/day. In still another embodiment, the barrier 100 comprises TiO₂ having a WVTR of less than approximately 0.5 g/m²/day. The barrier 100 may cover all or a portion of a surface of the substrate 110. The substrate 110 may be rigid or flexible. Flexible substrates may comprise, for example, a polymer material, such as polyethylene terephthalate (PET) (particularly biaxially oriented PET), biaxially oriented polypropylene (BOPP), plastic substrates for OLEDs, a plastic web, or a metallic material, such as metal web or foil. Rigid substrates may comprise glass, metal, or silicon, for example. Additionally, the substrate 110 may comprise other materials such as wire, flexible tubing, woven materials such as cloth, braided materials such as braided wire or rope, and non-woven sheet materials such as paper. Thus, the substrate 110 may take virtually any shape or size.

Additional layers of material or components may be interposed between the barrier 100 and the substrate 110. For example, display devices that are sensitive to gases or liquids, such as OLEDs, liquid crystal displays (LCDs), or light emitting diodes (LEDs), may be covered by and protected by the barrier 100. As illustrated in FIG. 2, a barrier 200 similar or identical to the barrier 100 may be formed on an opposing surface of the substrate 110.

According to one embodiment, one or two barriers 100, 200 are formed on the substrate 110 with an ALD process using TiCl₄ and water as precursors. For example, the substrate 110 may be exposed to the precursors in an alternating sequence, with consecutive exposures to the precursors being separated by isolation exposures to an inert gas, to result in the precursors reacting only at the surface of the substrate 110 to form a layer of TiO₂ thereon. According to a preferred embodiment, the substrate 110 is maintained at a temperature of less than approximately 100° C., and more preferably between approximately 5° C. and approximately 80° C. Thus, the substrate 110 may be processed at room temperature. In another embodiment, the substrate 110 may be maintained at a certain temperature by heating or cooling the substrate.

In one embodiment, TiO₂ thin films are formed with a radical-enhanced ALD process (REALD) of the kind generally described in Publication No. US 2008/0026162 A1 of Dickey et al., which is incorporated herein by reference. In some embodiments, a REALD process for forming metal oxide thin film barriers utilizes a first precursor source of a metal-containing compound, such as a metal halide like TiCl₄ for example, and a second precursor comprising a source of radicals reactive with the first precursor. The radicals may be generated by excitation of an oxidizing gas or other oxygen-containing compound that is dissociated by the excitation. Examples of such dissociable oxygen-containing compounds include alcohols, ethers, esters, organic acids such as acetic acid, and ketones. An exemplary REALD process for forming TiO₂ thin films utilizes TiCl₄ as a first precursor and atomic oxygen radicals (O) formed by excitation of an oxygen-containing compound or mixture selected from the group consisting of dry air, O₂, H₂O, CO, CO₂, NO, N₂O, NO₂, and mixtures thereof. In one embodiment for making TiO₂ thin films using a TiCl₄ as the first precursor, the oxygen-containing compound or mixture is excited by igniting a plasma from an inert gas, such as dry air, O₂, CO, CO₂, NO, N₂O, NO₂ or a mixture of any two or more such inert gases, using a DC glow discharge. In some embodiments, the same inert gas (inert with the first precursor) may be utilized as the radical source and as a purge gas or isolation gas in the reactors and deposition methods described below, as further described in Publication No. US 2008/0026162 A1.

In one configuration, a cross-flow traveling wave type ALD reactor is used to form one or more barriers on the substrate. One such traveling wave type reactor is the P400 reactor manufactured by Planar Systems Inc. of Beaverton, Oreg. If an alternating sequence of precursor pulses separated by purge pulses are applied to the substrate in a cross-flow reactor, the substrate temperature is preferably maintained between approximately 30° C. and 80° C., which provides desired barrier properties, but allows shorter purge times than when done at room temperature.

Other systems and methods may be used to form one or more barriers on the substrate. For example, the substrate may be transported multiple times between and through different precursor zones, which are separated by one or more isolation zones, in a manner described in Pub. No. US 2007/0224348 A1 or US 2008/0026162 A1, which are incorporated herein by reference. The substrate temperature is preferably maintained between room temperature (e.g., approximately 15° C. to approximately 21° C.) and approximately 80° C. In other embodiments, the temperature of the substrate and reactor may be maintained at temperatures below approximately 100° C., between approximately 5° C. and 80° C., between approximately 15° C. and 50° C., and between approximately 5° C. and approximately 35° C.

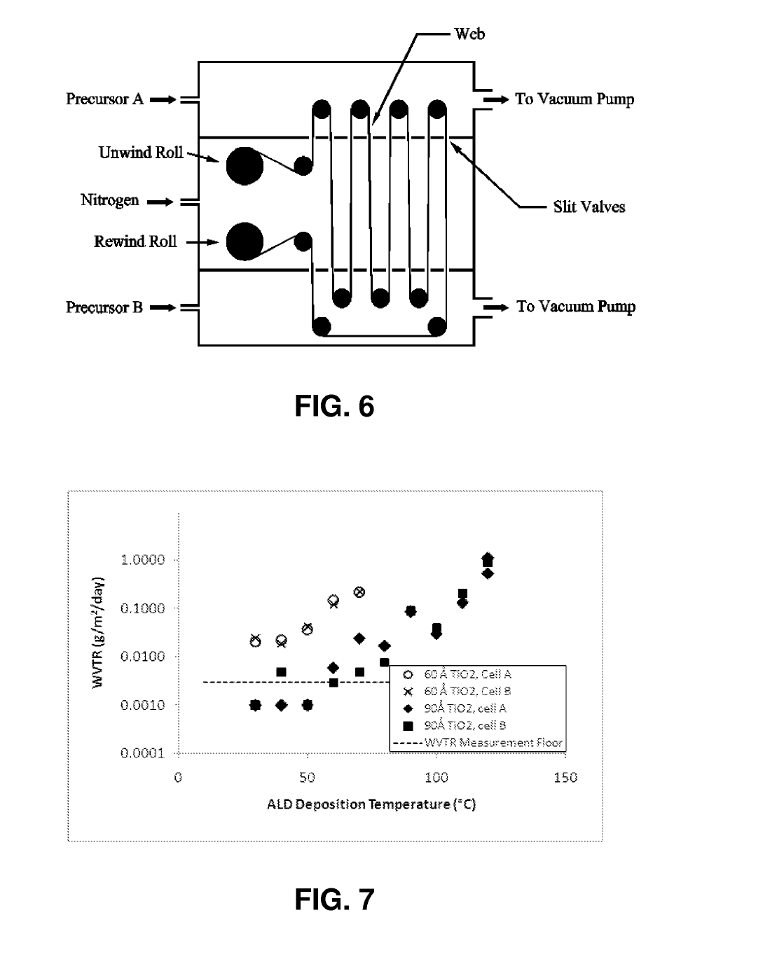

A schematic representation of a flexible web coating system consistent with US 2007/0224348 A1 is shown in FIG. 6 in a roll-to-roll configuration. With reference to FIG. 6, the substrate web is passed from an unwind roll through a sequence of slit valves from the central isolation zone (purge zone) and then between precursor A zone and precursor B zone multiple times, each time through the isolation zone, and finally to a rewind roll. A test reactor used for roll-to-roll experiments described below included a total of 16 pairs of slit valves, resulting in the equivalent of 8 ALD cycles per pass. The number of ALD cycles may be doubled by reversing the direction of the transport mechanism to rewind on the unwind roll. In other embodiments (not shown), a greater or lesser number of slits are included for performing a different number of ALD cycles in a single pass of the substrate between the unwind roll and rewind roll.

Barriers formed of TiO₂ by low temperature ALD may generally exhibit better barrier properties than Al₂O₃ barriers. For example, TiO₂ barriers may be characterized by a chemical resistance to certain corrosive environments. Additionally, TiO₂ barriers may be particularly resistant to permeation by water vapor in high temperature environments, high humidity environments, or both. Further, TiO₂ barriers may be better suited for flexible substrate applications than Al₂O₃ barriers because TiO₂ barriers may have a higher elasticity than Al₂O₃ barriers, and therefore less likely to fracture when the substrate is flexed.

Maintaining the substrate 110 at a temperature of less than approximately 100° C. during the thin film deposition process may offer one or more advantages. For example, lower temperatures may reduce stress between the barrier layer and the substrate caused by differences in coefficients of thermal expansion (or contraction) between the barrier and the substrate. The differences in coefficients of thermal expansion may be significant for oxide barriers deposited on metal (e.g., foil) or polymer substrates, such as PET or BOPP. Maintaining the substrate 110 at a temperature of less than approximately 100° C. may also help simplify the complexity of deposition equipment because materials and components used in the equipment do not need to be chosen and designed to accommodate higher temperatures. Additionally, maintaining the substrate 110 at a relatively low temperature, e.g., less than approximately 100° C. or less than 35° C., may reduce or eliminate the need for heaters, which may reduce system cost and result in reduced power consumption for large scale systems, such as industrial roll-to-roll coating equipment.

The systems and methods described herein, and the products thereof, have a wide range of applications. For example, the barriers formed by the methods may function as oxygen and moisture barriers for sensitive goods and packaging therefor, such as food packaging, medical devices, pharmaceutical products, and electrical devices, gas or chemical barriers for tubing, such as the plastic tubing used in chemical or medical applications, fire retardant barriers for woven materials, functional barriers to provide moisture or stain resistance, and hermetic seals for various devices, such as OLEDs or other electronic display devices.

Further, the TiO₂ barriers may be characterized by photo-catalytic properties. Thus, the TiO₂ barriers may function as self cleaning coatings (e.g., self cleaning glass) and anti-bacterial coatings (e.g., anti-bacterial coatings for wall tiles, medical packaging, and food packaging).

### Experimental Results

Various experiments were performed to form a gas and water vapor diffusion barrier for flexible substrates. For all the experiments described below, 0.005 inch thick Mylar™ biaxially oriented PET substrate films (DuPont Tejin Films LP) were used as the starting substrate. One set of experiments was performed using the P400 cross-flow ALD reactor and another set of experiments was performed using a roll-to-roll system described below with reference to FIG. 5, further details of which are described in Pub. No. US 2007/0224348 A1.

### Experiment Set 1

### Conventional Cross-Flow Traveling Wave ALD

TiO₂ films or barriers of various thicknesses were deposited on 0.005 inch thick Mylar™ PET substrates at various temperatures using a conventional cross-flow traveling wave type ALD process in the P400 reactor, with pulse valves. Water vapor transmission rate (WVTR) was then measured through the TiO₂-coated PET films. For each run, a piece approximately 18 inches long was cut from the PET substrate film rolls (each roll was approximately four inches wide by approximately 100 feet long). Each cut piece was placed in an oxygen asher (barrel reactor) for 3 minutes, at low power (100 W) prior to loading into the substrate chamber. No other cleaning or surface treatment was performed on the PET substrate.

TiCl₄ and water precursor sources were utilized. The precursor sources and substrate temperature for all runs were at ambient room temperature, which ranged from approximately 19° C. to approximately 22° C. To be certain that only one surface of the substrate was coated, each cut piece of PET substrate was placed on the flat bottom surface of the substrate chamber and weighted at the corners. A thick test run was made to confirm that the backside coating did not impinge on the area that was used for subsequent WVTR testing.

The pulse sequence and timing for each ALD cycle for all runs in the P400 reactor comprised 0.5 seconds TiCl₄, 20 seconds purge, 0.5 seconds H₂O, and 20 seconds purge. The flow rate for the nitrogen (N₂) carrier/purge gas in all of the runs made using the P400 was 1.5 liters/min and the pressure was approximately 0.8 Torr.

The WVTR of the coated substrates was measured using a water vapor transmission analyzer (WVTA) model 7001 manufactured by Illinois Instruments, Inc. of Johnsburg, Ill., USA. The TiO₂-coated PET substrates were clamped in a diffusion chamber of the model 7001 WVTA, which measures the WVTR by subjecting the coated substrates to test and carrier gases that attempt to permeate through the sample. The 7001 WVTA conforms to ISO 15105-2 and uses a modified ASTM standard that conforms to ISO 15106-3. WVTA measurements were conducted at 37.8° C. with a relative humidity of 90%. The 7001 WVTA has a lower sensitivity limit of 0.003 g/m²/day.

Although not used to gather the data below, more sensitive WVTR measurements may be obtained using tritiated water (HTO) as a radioactive tracer using a method similar or identical to that described in M. D. Groner, S. M. George, R. S. McLean, and P. F. Carcia, “Gas Diffusion Barriers on Polymers Using Al₂O₃ Atomic Layer Deposition,” Appl. Phys. Lett. 88, 051907, American Institute of Physics, 2006.

Initially, a thickness series was run to determine an appropriate thickness for testing the sensitivity of the process and resulting barrier layer properties to the temperature of the substrate during deposition. The number of cycles was varied over a large range, and the thickness of each TiO₂ barrier formed on the substrate was determined by measuring the film thickness on a witness piece of silicon with a thin layer of chemical oxide. The witness piece of silicon was prepared by dipping a polished silicon wafer in dilute hydrofluoric acid, followed by dips in SC1 and SC1 solutions to yield a starting substrate of approximately 7 Å SiO₂ on the surface of the polished silicon wafer. The thickness measurements were made using an ellipsometer, model AutoEL III™ manufactured by Rudolph Technologies, Inc. of Flanders, N.J.

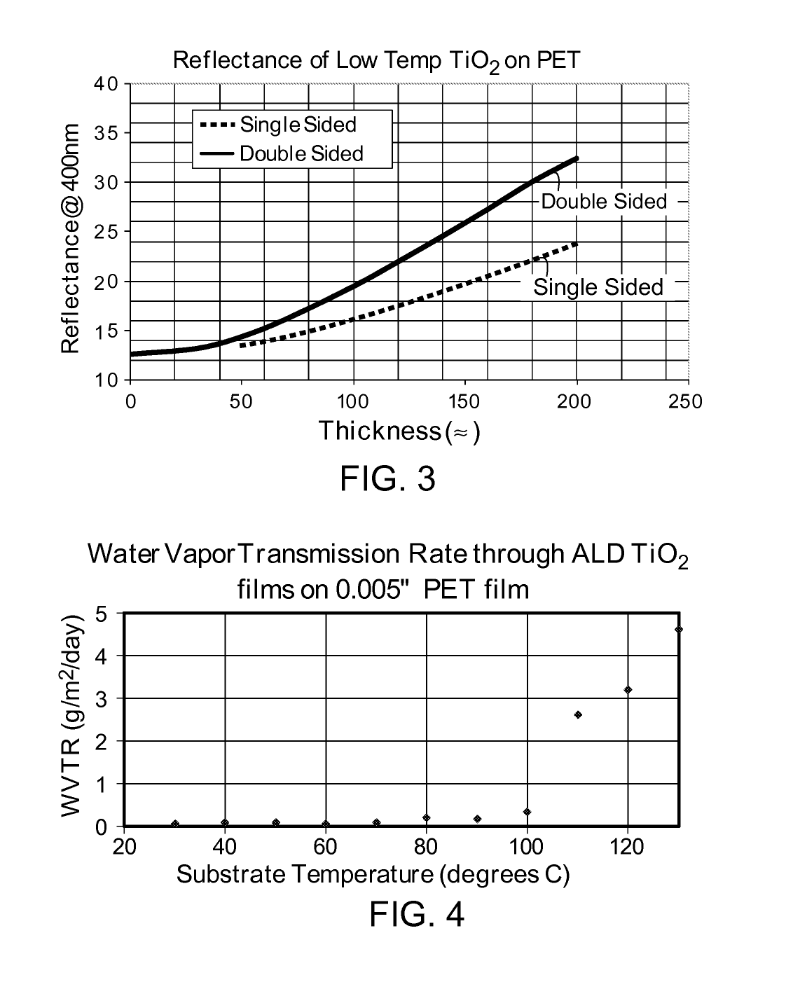

For a subset of runs, thickness was determined by measuring spectral reflectance within a wavelength range of approximately 380 nm to approximately 750 nm using a model Ultrascan XE™ spectrophotometer manufactured by Hunter Associates Laboratory, Inc. of Reston, Va. The spectral reflectance measurements at approximately 400 nm were compared to a chart of thickness versus reflectance at approximately 400 nm (see FIG. 3) to determine the thickness of the TiO₂ barrier. To determine the thickness of the TiO₂ barrier on each individual surface of a double sided coating, Kapton™ tape was applied to the PET substrate during deposition (one large piece on each of the two surfaces in different spots on the web) to mask those areas from coating on one of the surfaces. After depositing the TiO₂ barrier, the Kapton™ tape was removed from the PET substrate and the two areas were measured to determine the thickness on the opposite surface of each taped area. The thickness measurements made using the ellipsometer favorably compared to the thickness measurements determined from the spectral reflectance measurements and the chart shown in FIG. 3 (within the accuracy of the method, which is estimated to be within approximately 10 Å to approximately 20 Å for a 100 Å thick film on PET).

The chart of thickness versus reflectance at approximately 400 nm shown in FIG. 3 was generated using modeled data from thin film modeling software (TFCalc™ from Software Spectra, Inc. of Portland, Oreg.). Using the TFCalc software, the thickness of TiO₂ was varied to generate plots of reflectance (%) versus wavelength (nm) at various thicknesses (e.g., plots for a bare PET substrate, a 30 Å thick TiO₂ coating on both sides of the PET substrate, a 100 Å thick TiO₂ coating on both sides of the PET substrate, and so forth). The software itself generates the plots from known optical constants of TiO₂ (the optical constants may themselves be measured or derived from literature). The reflectance at approximately 400 nm for various thicknesses was pulled from the plots generated by the TFCalc software and recorded in Table 1. The chart of thickness versus reflectance at approximately 400 nm shown in FIG. 3 was created using the data in Table 1. The reflectance at approximately 400 nm was used because the sensitivity should be the highest at shorter wavelengths and 400 nm yields reliable, low-noise measurements using the spectrophotometer.

TABLE 1

| | |
|---|---|
| Thickness | Reflectance at approximately 400 nm |

| (Å) | Single Sided | Double Sided |
|---|---|---|
| 0 | 12.5 | 12.5 |
| 30 | — | 13.1 |
| 50 | 13.4 | 14.3 |
| 70 | 14.3 | 16.1 |
| 100 | 16.0 | 19.4 |
| 120 | 17.4 | 21.9 |
| 140 | 19.0 | 24.5 |
| 160 | 20.5 | 27.2 |
| 180 | 22.1 | 30.0 |
| 200 | 23.8 | 32.4 |

The results from the thickness experiments are shown in Table 2. For comparison, the WVTR through an uncoated sample of the PET substrate was approximately 5.5 g/m²/day.

TABLE 2

| | | | | |
|---|---|---|---|---|
| | | WVTR | WVTR | WVTR |
| # | Measured | (g/m²/day) | (g/m²/day) | (g/m²/day) |
| cycles | thickness | Cell A | Cell B | Average |

| 35 | 27 | Å | 4.5 | 4.3 | 4.4 |
|---|---|---|---|---|---|
| 50 | 36 | Å | 0.84 | 0.81 | 0.83 |
| 70 | 53 | Å | 0.23 | 0.13 | 0.18 |
| 100 | 77 | Å | 0.25 | 0.31 | 0.28 |
| 200 | 153 | Å | 0.05 | 0.32 | 0.19 |
| 400 | NM | | 0.02 | 0.26 | 0.14 |
| 700 | 523 | Å | 0.63 | 0.69 | 0.66 |
| 1000 | 740 | Å | 0.57 | 0.53 | 0.55 |

As shown in Table 2, the vapor permeability increases for some of the thickest films (e.g., 523 Å and 740 Å). This phenomenon has been observed previously in other research. Inspection of the thicker film samples subsequent to WVTR testing revealed that the O-ring used to seal the sample appears to damage the surface underneath the seal, particularly on thicker films, which are not as flexible and elastic as thinner ones. Thus, the increased WVTR data for the thicker films may be an artifact of the measurement technique.

Based on the thickness series, it was determined that a target barrier thickness of approximately 75 Å would be used for temperature variation experiments, as the approximately 75 Å barrier thickness appears to provide an adequate barrier, but perhaps would be more sensitive to variations in film properties than a thicker layer.

For the temperature variation experiments, all variables were kept constant except for the substrate temperature, and the number of cycles, which were varied to compensate for the change in growth rate with temperature, to achieve the desired thickness of approximately 75 Å. The results from the temperature variation experiments are summarized in Table 3 and FIG. 4.

TABLE 3

| Substrate | | # | Measured | WVTR (g/m²/day) | | |
|---|---|---|---|---|---|---|
| Temperature | | cycles | thickness | Cell A | Cell B | Average |
| 30 | C. | 100 | 76 Å | 0.06 | 0.05 | 0.06 |
| 40 | C. | 105 | 75 Å | 0.07 | 0.09 | 0.08 |
| 50 | C. | 114 | 82 Å | 0.04 | 0.09 | 0.07 |
| 60 | C. | 114 | 83 Å | 0.04 | 0.07 | 0.06 |
| 70 | C. | 112 | 72 Å | 0.07 | 0.09 | 0.08 |
| 80 | C. | 120 | 74 Å | 0.22 | 0.18 | 0.20 |
| 90 | C. | 130 | 78 Å | 0.18 | 0.15 | 0.17 |
| 100 | C. | 135 | 77 Å | 0.31 | 0.32 | 0.32 |
| 110 | C. | 140 | 75 Å | 3.0 | 2.1 | 2.6 |
| 120 | C. | 150 | 82 Å | 3.7 | 2.7 | 3.2 |
| 130 | C. | 150 | 74 Å | 4.5 | 4.7 | 4.6 |

Because the substrate used was untreated PET, one concern was that the higher deposition temperatures (substrate temperatures) might compromise the overall substrate properties, and therefore the system, including the substrate and ALD TiO₂ coating. To test this possibility, an additional run was made, in which the substrate was first heated in the reactor to 120° C. and then cooled down to 50° C. After the substrate was cooled to 50° C., a 75 Å film was deposited on the substrate and the WVTR measured. This sample yielded a WVTR of 0.38 g/m²/day, which suggests that while substrate damage resulting from high substrate temperatures may affect the test results, substrate damage resulting from high substrate temperatures is not the dominant cause of higher WVTR observed in the substrate temperature series shown in Table 3. One possible explanation of why higher WVTR are observed above 100° C. is that the TiO₂ may develop some crystallinity (e.g., polycrystalline grains) above 100° C. and the grain boundaries may provide a path for vapor migration. Below 100° C. the TiO₂ is likely completely amorphous or substantially completely amorphous.

Additionally, a brief set of sensitivity runs were made to determine if the barrier properties of the film were substantially affected by changes to the cycle parameters. Purge times were varied between 2 seconds and 100 seconds, and pulse times were varied between 0.1 seconds and 5 seconds. For all of the films made in this range of parametric space, the WVTR ranged between 0.09 and 0.20, with no systematic correlation observed.

Experimental deposition runs were also performed in the P400 reactor to simulate a double sided coating that might be made in a roll-to-roll system. One run was made using 2 second pulses of TiCl₄ and water, and 3 second purges, at room temperature, and comprised 100 cycles. The measured TiO₂ film thickness on a silicon witness was 95 Å, which indicates 95 Å TiO₂ films were formed on each side of the PET coupon. In one cell of the WVTR analyzer, the measurement result was 0.000 g/m²/day, and in the other cell, the WVTR was 0.007 g/m²/day, suggesting that the permeability is within the baseline sensitivity of the WVTA instrument.

FIG. 7 is a plot of the results of additional double-sided deposition experiments performed in the P400 cross-flow reactor. In FIG. 7, the Cell A and Cell B legends refer to the two parallel test cells in the WVTR measurement instrument. FIG. 7 illustrates the effect of deposition temperature on WVTR for PET films coated on both sides with 60 Å and 90 Å TiO₂ films. The WVTR for 60 Å TiO₂ barriers appear to level off at about 0.02 g/m²/day at deposition temperatures around 40-50° C.

### Experiment Set 2

### “Roll-to-Roll” ALD in Loop Mode

A second set of experiments was performed utilizing a prototype roll-to-roll deposition system consistent with the systems described in Pub. No. US 2007/0224348 A1, operating in loop mode. FIG. 5 illustrates a “loop-mode” configuration that wraps the substrate into an endless band (loop), which includes a single path comprising one cycle, from the central isolation zone 510, into the TiCl₄ precursor zone 520, back to the isolation zone 510, to the oxygen-containing precursor zone 530, and to finish back in the isolation zone 510. As the web travels between zones it passes through slit valves, which are just slots cut in the plates 540, 550 that separate the different zones. In this configuration the web can be passed repeatedly through the precursor and isolation zones in a closed loop. (The system is referred to herein as the “roll-to-roll” deposition system, even though the loop substrate configuration used for experimental purposes does not involve transporting the substrate from a feed roll to an uptake roll.) In the loop configuration, a full traverse of the loop path constitutes a single cycle, and the band is circulated along this path x number of times to attain x number of ALD cycles. As with runs in the P400 reactor, the substrate was pretreated in an oxygen plasma, but no other cleaning or surface preparation was done. To form a complete loop band, approximately 86 inches of the 4 inch wide PET substrate was used, and the ends of the substrate were taped together using Kapton™ tape. The system was then pumped down and left to outgas overnight.

To begin the run, high purity nitrogen was introduced into the isolation zone 510 of the roll-to-roll deposition system approximately at location L1. The flow rate of nitrogen was approximately 4.4 liters/min. and the pressure in the isolation zone was approximately 1.0 Torr. A pressure drop of approximately 0.02 Torr was measured between the isolation zone and the precursor zones. After purging the isolation and deposition zones, the valves to the TiCl₄ source (top zone) and water source (bottom zone) were both opened and the substrate was sent into motion with an approximate period (cycle time) of 5 seconds, which translates to a web speed of approximately 17 inches per second (approximately 0.44 m/sec). The TiCl₄ was introduced into the top zone approximately at location L2 and the water (vapor) was introduced into the bottom zone approximately at location L3. This situation was maintained for approximately 12 minutes, leading to a total number of approximately 144 cycles. The path length through each element of the cycle included 21 inches in the TiCl₄ zone, 17 inches in the isolation zone, 24 inches in the water zone, and 24 inches in the isolation zone and around the drive roller. Thus, for the web speed of five seconds per cycle, the approximate residence times in each zone include 1.2 seconds in the TiCl₄ zone, 1.0 second in the isolation zone, 1.4 seconds in the water zone, and 1.4 seconds in the isolation zone.

The water and TiCl₄ sources, along with the vacuum system and web, were all nominally at room temperature during the run. A thermocouple located inside the system approximately as shown in FIG. 5 indicated a temperature of approximately 21° C. Following completion of the run, the system was purged and pumped, and the band was then removed. The film thickness on each surface of the web was measured using reflective spectrometry to determine approximate film thickness, and samples were taken for WVTR measurement.

Reflectance measurements indicated a thickness of approximately 150 Å on the outside surface of the web and approximately 70 Å on the inside surface of the web. A thickness of approximately 150 Å on the outside surface of the web and approximately 70 Å on the inside surface of the web was also observed when the substrate was set in motion before introducing the precursors into the chambers. Because in general, the growth rate increases by increasing the dose strength, decreasing the isolation (purge) time, or both, the difference between the thicknesses of the two surfaces may be caused by asymmetry in the system resulting in differing effective dose strengths of precursors and isolation (purge) gas. For example, by varying the dose strengths and purge times in the P400 reactor, growth rates at room temperature have been observed to change from approximately 0.6 Å per cycle to over approximately 1 Å per cycle. One such experiment in the P400 reactor has shown that the growth rate increased by approximately 30 percent when the dose strength of both precursors was increased from 0.5 seconds to 2.5 seconds (with 20 second purges between the application of the precursors). Thus, the difference in growth rates (and therefore the barrier layer thickness) observed between the inner and outer surfaces of the loop substrate using the roll-to-roll system is consistent with the test results observed using the P400 reactor.

There are several possible theories explaining why the growth rate increases when the dose strength is increased or the purge/isolation time is decreased. For example, larger doses may further saturate the surfaces, resulting in imperfect subsequent purges (e.g., leaving a small amount of water vapor, TiCl₄, or both, near surfaces during the subsequent cycle step that may increase the growth rate). Larger doses may also result in some bulk absorption of precursors into the substrates (e.g., the PET substrate) that is not fully removed during the purge/isolation step. Bulk absorbed precursors may act as small virtual sources of precursors (although this may only happen before the substrate is “sealed” by the accumulating coating). Further, longer purge/isolation times may result in more desorption of one of the precursors.

Additionally, non-ALD growth may play a small role in generating the difference between the thicknesses of the two surfaces, but were not found to be the dominant factor. To determine whether non-ALD growth is causing the difference in thicknesses between the two surfaces, a test was performed that exposed the web to the precursors while the web remained stationary. No significant film growth was observed after exposing the web to the precursors while the web remained stationary, which suggests that non-ALD growth is not the dominate factor in causing the difference in thicknesses between the two surfaces. Further, it has been observed that the growth rate is affected more by the number of cycles than the total time the substrate is exposed to the precursors. For example, two test runs were made with different coating speeds. The growth rate per cycle (on the outside surface) for a test run with an 8 meters per second coating speed was approximately 50 percent of a test run with a 0.4 meters per second coating speed.

Additional experiments were performed to determine whether the TiCl₄ source entry point affects the thickness on both sides of the substrate. By introducing the TiCl₄ at approximately location L4, the thickness on the outside surface of the web was approximately equal to the thickness on the inside surface of the web.

The WVTR tests observed from the films deposited using the roll-to-roll system in loop mode are consistent with the double-sided coating from the P400 pulse-based reactor. For samples of 0.005-inch thick PET coated with TiO₂ films approximately 150 Å thick on the outside surface of the web and approximately 70 Å on the inside surface of the web, in one cell of the WVTR measurement system values of 0.000 g/m²/day were reached and in the other cell a value of 0.002 g/m²/day was reached, indicating that permeation was within the sensitivity floor of the WVTA system (specified at 0.003 g/m²/day).

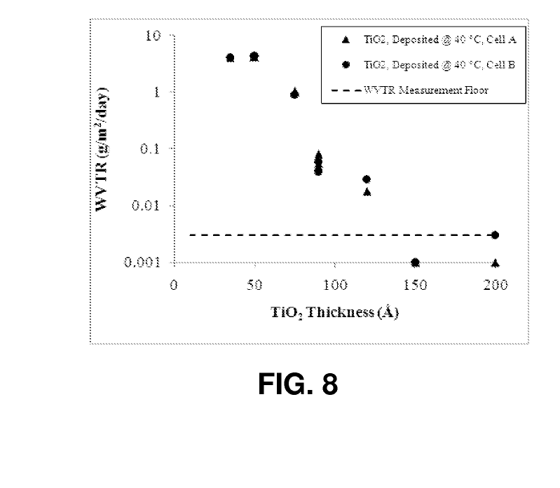

FIG. 8 plots water vapor transmission rates for PET films coated with various thicknesses of TiO₂ in the ALD web coater of FIG. 5 operating at 40° C. in loop mode with a web transport speed of 1 m/second.

Using the roll-to-roll system offers several advantages over the P400 pulse-based reactor. For example, thin and transparent dielectric barrier films can be deposited on a plastic web in a roll-to-roll or loop configuration in less time than the P400 pulse-based reactor by eliminating the relatively long pulse and purge times. Additionally, since the precursors are isolated from one another at all times (except for the monolayer chemisorbed on the web), the barrier film is deposited only on the web, and not on the reaction chamber walls or other components of the deposition system. Thus, using the roll-to-roll system, films having a thickness of approximately 40 Å to approximately 50 Å and a WVTR within the range of approximately 0.1 g/m²/day to approximately 0.4 g/m²/day can be formed in approximately 30 ALD cycles to approximately 100 ALD cycles (depending on the dose strength and coating speed).

### Example 3

### Radical Enhanced ALD in Loop Mode

A third experiment involved the use of the web coater system of FIG. 6 operating in loop mode with TiCl₄ as the first precursor and CO₂ as the oxidizing gas, with a DC glow discharge (not shown) igniting a plasma from the CO₂ gas in the precursor zone 530. Nitrogen was utilized as the isolation (purge) gas. The 2.2 meter substrate loop was transported at approximately 0.1 m/sec (22 second cycle time). After 37 cycles, a 30 Å film was formed, which was measured to have WVTR of about 0.02 grams/m²/day (@ 38 degrees C., 90% relative humidity). Thicker, 40 Å TiO₂ films formed by this same method at temperatures of 40° C. and room temperature (approximately 20° C.) exhibited vapor barrier performance beyond the sensitivity limit of the WVTA (i.e., less than 0.003 g/m²/day).

The refractive index of the film made from the CO₂ plasma (˜2.5 @ 500 nm wavelength) is significantly higher than that made from water vapor at low temperatures (˜2.3 @ 500 nm wavelength), and matches that made with conventional ALD processes based on TiCl₄ and water at a temperature exceeding 200° C. However, the WVTR performance of TiO₂ barrier layers made by REALD with CO₂ plasma indicates that the barrier layer likely remains amorphous, unlike films made from TiCl₄ and water at higher temperatures, which do not make good barriers.

### CONCLUSION

Food packaging barriers, which have typically been constructed using evaporated aluminum metal (evaporation deposition), generally have a WVTR within the range of approximately 0.1 g/m²/day to approximately 0.5 g/m²/day at thicknesses greater than 200 Å. Thus, the test results observed from the web coater experiments and the P400 pulse-based reactor illustrate that TiO₂ barriers formed using the methods described herein are more than adequate for food packaging. Forming food packaging TiO₂ barriers using ALD methods offers several advantages over evaporated aluminum metal barriers. For example, the test results shown above illustrate that TiO₂ barriers having a thickness in the range of approximately 30 Å to 70 Å formed using the web coater system described herein yield a WVTR suitable for food packaging applications in approximately 40 to approximately 70 ALD cycles, which can be done with a relatively simple and compact roll-to-roll deposition system consistent with US 2007/0224348 A1. In comparison, known evaporated aluminum metal films have a thickness of approximately 200 Å or more, and evaporated and sputtered oxides for transparent barriers, such as SiO₂ and Al₂O₃, have a thickness of approximately 200 Å to approximately 2000 Å.

FIG. 7 illustrates a WVTR of less than 0.5 g/m²/day for 60 Å TiO₂ barriers formed at around 70-80° C. Similar WVTR performance can be obtained with TiO₂ barriers less than 50 Å thick deposited at lower temperatures. In other embodiments, WVTR of less than 0.01 g/m²/day can be achieved by similar low temperature deposition of TiO₂ barriers having a thickness of less than 100 Å. Further, WVTR performance of better (less) than 0.0001 g/m²/day is expected for low temperature deposition of TiO₂ barriers having a thickness of less than 150 Å.

Additionally, the methods described herein are likely capable of generating TiO₂ barriers having a WVTR suitable for other applications, such as barrier layers for thin film solar PV, OLED lighting, and flexible electronics, which may require a WVTR of less than approximately 10⁻⁵ g/m²/day.

It will be obvious to those having skill in the art that many changes may be made to the details of the above-described embodiments without departing from the underlying principles of the invention. The scope of the present invention should, therefore, be determined only by the following claims.

1. A vapor barrier deposited onto a substrate, the barrier comprising:
a thin film of metal oxide less than 150 angstroms thick and having a water vapor transmission rate of less than 0.5 g/m²/day.

2. The vapor barrier of claim 1, wherein the thin film has a water vapor transmission rate of less than approximately 0.0001 g/m²/day.

3. The vapor barrier of claim 1, wherein the thin film is less than 50 angstroms thick.

4. The vapor barrier of claim 1, wherein the thin film is less than 100 angstroms thick and has a water vapor transmission rate of less than approximately 0.01 g/m²/day.

5. The vapor barrier of claim 1, wherein the thin film of metal oxide consists essentially of titanium dioxide.

6. The vapor barrier of claim 1, wherein the thin film coats opposite sides of the substrate.

7. The vapor barrier of claim 1, wherein the substrate is a flexible polymer film.

8. The vapor barrier of claim 1, wherein the thin film has photo-catalytic properties.

9. A packaging film coated with the vapor barrier of claim 1, for use in packaging food, medicines, medical devices, electronics, and the like.

10. An electrical device coated with the vapor barrier of claim 1.

11. A method of depositing a barrier layer onto a substrate, comprising:
while maintaining the surface temperature of the substrate at less than 100° C., repeating the following steps (a) and (b) in alternating sequence to thereby form a thin film of titanium dioxide on the substrate:
(a) exposing the substrate to a gaseous first precursor including TiCl₄; and
(b) exposing the substrate to a gaseous oxygen-containing second precursor.

12. The method of claim 11, further comprising separating consecutive exposures of the substrate to the first and second precursors with isolating exposures to an inert gas.

13. The method of claim 11, wherein the oxygen-containing second precursor is formed by excitation of an oxygen-containing compound or mixture selected from the group consisting of dry air, O₂, H₂O, CO, CO₂, NO, N₂O, NO₂, and mixtures thereof.

14. The method of claim 11, the first and second precursors are introduced in respective first and second precursor zones, which are separated by an isolation zone into which an inert gas is introduced, and further comprising:
transporting the substrate back and forth between the first and second precursor zones multiple times, and each time through isolation zone.

15. The method of claim 14, wherein the substrate is transported at a rate between about 0.2 meter per second and 10 meters per second.

16. The method of claim 11, wherein the substrate is a flexible web material.

17. The method of claim 11, wherein the second precursor includes a plasma.

18. The method of claim 11, wherein the surface temperature of the substrate is maintained between approximately 5° C. and 80° C. during deposition of the barrier layer.

19. The method of claim 11, wherein the surface temperature of the substrate is maintained between approximately 15° C. and 50° C. during deposition of the barrier layer.

20. The method of claim 11, further comprising depositing the thin film on opposite sides of the substrate.

21. The method of claim 11, further comprising pre-treating the substrate with an oxygen plasma prior to commencing steps (a) and (b).

22. A barrier layer made by atomic layer deposition of a titanium dioxide thin film onto a substrate at a temperature of less than 100° C., the barrier layer having a water vapor transmission rate of less than 0.5 g/m²/day.

23. The barrier layer of claim 22, wherein the thin film has a thickness of less than 100 angstroms and a water vapor transmission rate of less than approximately 0.01 g/m²/day.

24. The barrier layer of claim 22, wherein the thin film has a thickness of less than 150 angstroms water vapor transmission rate of less than approximately 0.0001 g/m²/day.

25. The barrier layer of claim 22, wherein the thin film is less than approximately 50 angstroms thick.

26. The barrier layer of claim 22, wherein the thin film is substantially completely amorphous.

27. The barrier layer of claim 22, wherein the thin film is deposited onto a flexible substrate.

28. The barrier layer of claim 22, wherein the thin film has photo-catalytic properties.

29. A packaging film coated with the barrier layer of claim 22, for use in packaging food, medicines, medical devices, electronics, and the like.

30. An electrical device coated with the barrier layer of claim 22.

31. The barrier layer of claim 22, wherein the atomic layer deposition of TiO₂ includes repeating the following steps (a) and (b) in alternating sequence:
(a) exposing the substrate to a gaseous first precursor including TiCl₄; and
(b) exposing the substrate to a gaseous oxygen-containing second precursor.

32. The barrier layer of claim 30, wherein the atomic layer deposition of TiO₂ further includes separating consecutive exposures of the substrate to the first and second precursors with exposures to an inert gas.

33. The barrier layer of claim 30, wherein the oxygen-containing second precursor is formed by excitation of an oxygen-containing compound or mixture selected from the group consisting of dry air, O₂, H₂O, CO, CO₂, NO, N₂O, NO₂, and mixtures thereof.
